(19) United States
(12) Patent Application Publication
(10) Pub. No.: US 2009/0085065 A1
(43) Pub. Date: Apr. 2, 2009

(54) METHOD TO FABRICATE III-N SEMICONDUCTOR DEVICES ON THE N-FACE OF LAYERS WHICH ARE GROWN IN THE III-FACE DIRECTION USING WAFER BONDING AND SUBSTRATE REMOVAL

(75) Inventors: Umesh K. Mishra, Montecito, CA (US); Lee S. McCarthy, Santa Barbara, CA (US); Chang Soo Suh, Goleta, CA (US); Siddharth Rajan, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/059,907

(22) Filed: Mar. 31, 2008

Related U.S. Application Data
(60) Provisional application No. 60/908,917, filed on Mar. 29, 2007.
(60) Provisional application No. 60/908,914, filed on Mar. 29, 2007.
(60) Provisional application No. 60/908,919, filed on Mar. 29, 2007.

(51) Int. Cl. H01L 29/778; H01L 21/18; H01L 21/20

(52) U.S. Cl. 257/194; 438/455; 438/483; 257/E21.088; 257/E29.246; 257/E21.09

(57) ABSTRACT

A method for fabricating III-N semiconductor devices on the N-face of layers comprising (a) growing a III-nitride semiconductor device structure in a Ga-polar direction on a substrate, (b) attaching a Ga face of the III-nitride semiconductor device structure to a host substrate, and (c) removing the substrate to expose the N-face surface of the III-nitride semiconductor device structure. An N-polar (000-1) oriented III-nitride semiconductor device is also disclosed, comprising one or more (000-1) oriented nitride layers, each having an N-face opposite a group III-face, wherein at least one N-face is an at least partially exposed N-face, and a host substrate attached to one of the group III-faces.

### CROSS-REFERENCE TO RELATED APPLICATIONS

This application claims the benefit under 35 U.S.C. Section 119(e) of the following co-pending and commonly-assigned U.S. patent application:

U.S. Provisional Patent Application Ser. No. 60/908,917, filed on Mar. 29, 2007, by Umesh K. Mishra, Lee S. McCarthy, Chang Soo Suh, and Siddharth Rajan, entitled “METHOD TO FABRICATE III-N SEMICONDUCTOR DEVICES ON THE N-FACE OF LAYERS WHICH ARE GROWN IN THE III-FACE DIRECTION USING WAFER BONDING AND SUBSTRATE REMOVAL,” attorneys docket number 30794.216-US-P1 (2007-336);

which application is incorporated by reference herein.

This application is related to the following co-pending and commonly assigned applications:

U.S. Utility patent application Ser. No. ______, filed on same date herewith, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC RESISTANCE”, attorney's docket number 30794.215-US-U1 (2007-269), which application claims priority under Section 119(e) of U.S. Provisional Patent Application Ser. No. 60/908,914, filed on Mar. 29, 2007, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC RESISTANCE,” attorneys docket number 30794.215-US-P1 (2007-269); and

U.S. Utility patent application Ser. No. ______, filed on same date herewith, by Umesh K. Mishra, Michael Grundmann, Steven P. Denbaars, and Shuji Nakamura, entitled “DUAL SURFACE-ROUGHENED N-FACE HIGH-BRIGHTNESS LED”, attorney's docket number 30794.217-US-U1 (2007-279), which application claims priority under Section 119(e) of U.S. Provisional Application Ser. No. 60/908,919 filed on Mar. 29, 2007, by Umesh K. Mishra, Michael Grundmann, Steven P. Denbaars, and Shuji Nakamura, entitled “DUAL SURFACE-ROUGHENED N-FACE HIGH-BRIGHTNESS LED” attorneys' docket number 30794.217-US-P1 (2007-279-1);

which applications are incorporated by reference herein.

### BACKGROUND OF THE INVENTION

1. Field of the Invention

The present invention is related to a method for fabrication of nitrogen face (N-face) structures using conventional gallium face (Ga-face) growth techniques.

2. Description of the Related Art

There are several methods of obtaining nitrogen-polar (N-polar) devices. The most direct method is to use a substrate that naturally provides for the N-polarity such as the carbon face (C-face) of silicon carbide (SiC) or by using surface treatments on substrates, such as sapphire, to generate the buffer that leads to N-polar devices.

### SUMMARY OF THE INVENTION

The present invention discloses a method for fabricating III-nitride semiconductor devices on the nitrogen-face of layers, comprising growing a III-nitride semiconductor device structure in a III-polar direction on a growth substrate, attaching a III-face of the III-nitride semiconductor device structure to a host substrate, and at least partially removing the growth substrate to expose a nitrogen-face of the III-nitride semiconductor device structure. The method may further comprise using or processing one or more exposed nitrogen faces of the semiconductor device structure to form a device. The growth substrate may be silicon. A device, such as a High Electron Mobility Transistor (HEMT), may be fabricated using the method.

The present invention further discloses an N-polar (000-1) oriented III-nitride semiconductor device, comprising one or more (000-1) oriented nitride layers, each having an N-face opposite a group III-face, wherein at least one N-face is at least partially exposed, and a host or carrier substrate is attached to a terminating group III-face. One or more of the N-faces may be processed. The device may further comprise a stack of the (000-1) oriented nitride layers, with the host substrate attached to a group III-face terminating the stack.

The one or more (000-1) oriented nitride layers may be a first AlGaN layer, a first GaN layer on the first AlGaN layer, a second AlGaN layer on the first GaN layer, a second GaN layer on the second AlGaN layer, and a two dimensional electron gas may be confined in the second GaN layer. A gate may be processed on the at least partially exposed N-face of the first AlGaN layer, and a source and a drain may electrically contact the at least partially exposed N-face of the first GaN layer.

The device may be a high electron mobility transistor (HEMT).

The present invention discloses a method for fabricating III-nitride semiconductor devices, comprising growing the semiconductor device in the Ga-face or III-face orientation; and processing the semiconductor nitride device in the nitrogen face (N-face) orientation, by processing one or more N-faces of the device.

### BRIEF DESCRIPTION OF THE DRAWINGS

Referring now to the drawings in which like reference numbers represent corresponding parts throughout:

FIG. 1 is a schematic illustrating the method of the present invention, wherein FIG. 1(a) illustrates an AlGaInN device structure grown in the gallium polar (Ga-polar) manner on a substrate, FIG. 1(b) illustrates attachment of the AlGaInN device structure to a host substrate, and FIG. 1(c) illustrates removal of the substrate to expose the N-face surface of the AlGaInN device structure to be processed.

FIG. 2 is a schematic comparing conventional techniques with the method of the present invention, wherein FIG. 2(a) illustrates a conventional Ga-polar design, FIG. 2(b) illustrates a conventional N-polar design, and FIG. 2(c) illustrates the N-polar design proposed in the new method of the present invention.

FIG. 3(a) is a schematic showing an N-polar E-mode device fabricated on a conventionally grown N-face material and FIG. 3(b) shows an N-face E-mode device fabricated on N-face material obtained through the newly proposed method of the present invention.

### DETAILED DESCRIPTION OF THE INVENTION

In the following description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

Overview

The present invention discloses that III-face or gallium face (Ga-face) III-nitride devices, and in particular, enhancement mode (E-mode) III-N devices, for which III-face fabrication is ideally suited, can be fabricated by the growth of materials in the III-face or Ga-face orientation, but processed in the nitrogen face (N-face) orientation, by bonding the epitaxial structure to a carrier wafer and removing the growth substrate. The present invention allows the fabrication of novel E-mode N-face structures using conventional Ga-face growth techniques.

Technical Description

In this disclosure, a new method to develop N-polar devices is proposed, wherein the device structure is grown in a Ga-polar manner but the design of the structure, including but not limited to the sequence and compositions of the layers comprising the device structures, placement of doping, etc., is designed with the intent of processing primarily the N-face of the device. This typically results in a device design substantially different from devices designed for processing the Ga-face of the material, as is the conventional case.

In particular, the method of the present invention can be used to fabricate enhancement mode (E-mode) high electron mobility transistors (HEMTs) in the III-N material system. This is achieved by attaching the as-grown material, with or without additional interlayers (such as SiNₓ, AlN, Diamond, SiC or SiO₂, for example), which can be used for a variety of purposes including passivation and/or planarization and/or thermal conductivity, to a host substrate, which may be a metal, semimetal, semiconductor or a dielectric or a combination of these. The substrate on which the material with the Ga-polar surface is grown is then removed, exposing the N-face surface, which can be subsequently processed in a manner similar to that used for as-grown N-face devices.

The N-face structures to be processed can also include improvements such as ion implantation, subsequent regrowth, or fluorine treatment to reduce access resistance or provide other conductivity engineering such as reduction in gate leakage, increase in buffer breakdown, electric field shaping, etc.

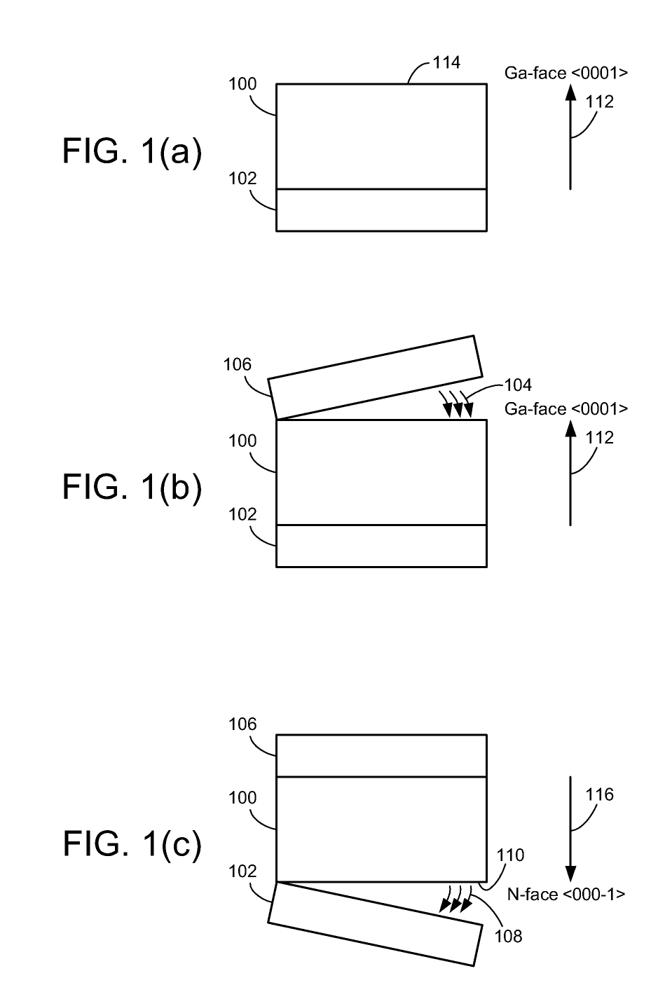

The substrate removal may be either complete or partial. The method of the present invention is shown schematically in FIGS. 1(a), 1(b) and 1(c) for the case of complete removal of the substrate. FIG. 1 is a schematic illustrating the method of the present invention, wherein FIG. 1(a) illustrates the step of growing an AlGaInN device structure 100, in a Ga-polar manner on a growth substrate for Ga-polar growth 102, FIG. 1(b) illustrates the step of attaching 104 the AlGaInN device structure 100 to a host substrate 106, and FIG. 1(c) illustrates the step of removing 108 the growth substrate 102 to expose the N-face surface 110 of the AlGaInN device structure 100 to be processed. The attaching 104 may be achieved, for example, by wafer bonding.

In FIGS. 1(a) and 1(b), the arrow 112 points in the Ga-face <0001> direction, towards the Ga-face surface 114 of the AlGaInN 100 (consequently, the opposite surface 110 in FIG. 1(c), is N-face). AlGaInN 100 grown in a Ga-polar manner (along the <0001> direction), as in FIG. 1(a), has a last grown surface 114, which is Ga-face, and a first grown surface 110, which is N-face. In FIG. 1(c), the arrow 116 indicates the N-face <000-1> direction or N-polar orientation, and therefore points towards the N-face surface 110 of the AlGaInN 100.

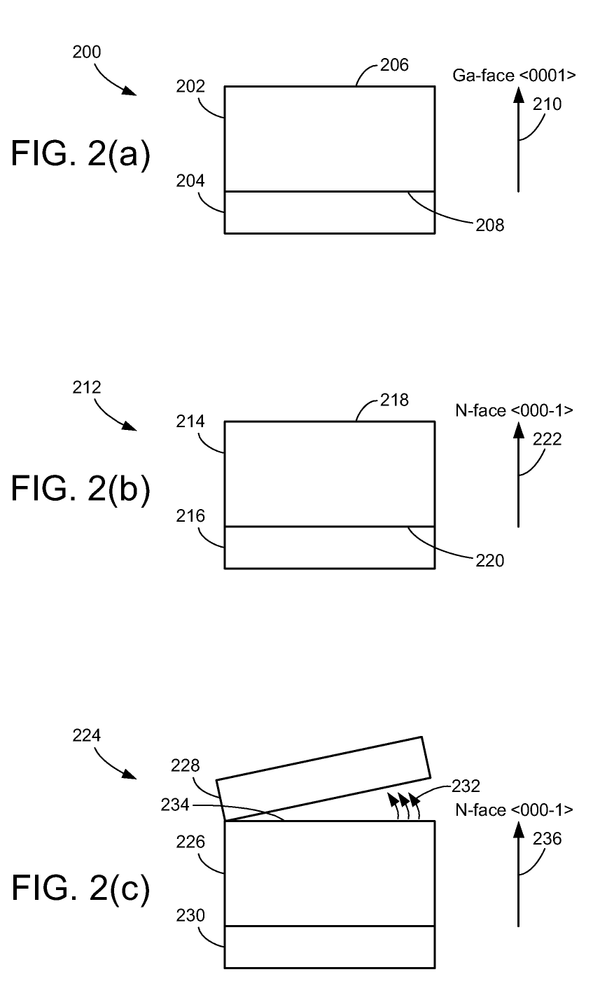

The difference between processing a Ga-polar material as is conventionally designed, the N-polar material as it is conventionally designed, and a N-polar device designed in this new method is shown in FIGS. 2(a), 2(b) and 2(c).

FIG. 2(a) illustrates a conventional Ga-polar design 200, wherein an AlGaInN structure 202 is grown in the Ga-face direction on a substrate for Ga-polar growth 204, so that the last grown surface 206 of the AlGaInN 202 has a Ga-face and the first grown surface is an N-face 208. The arrow 210 indicates the Ga-face direction <0001>.

FIG. 2(b) illustrates a conventional N-polar design 212, wherein the AlGaInN structure 214 is grown in an N-face <000-1> direction on a substrate for N-polar growth 216, so that the last grown surface of the AlGaInN 214 is an N-face 218 and the first grown surface is a Ga-face 220. Arrow 222 points in the N-face direction <000-1> (towards the N-face surface 218 of the AlGaInN 214, and consequently, the opposite surface 220 is Ga-face).

FIG. 2(c) illustrates the N-polar design 224 proposed in the new method of the present invention, comprising growing an AlGaInN device structure 226 in a Ga-polar manner on a growth substrate for Ga-polar growth 228, attaching the AlGaInN device structure 226 to a host substrate 230, and removing 232 the growth substrate 228 to expose the N-face surface 234 of the AlGaInN device structure 226. The arrow 236 points in the N-face direction <000-1> of the crystal 226, towards the N-face surface 234.

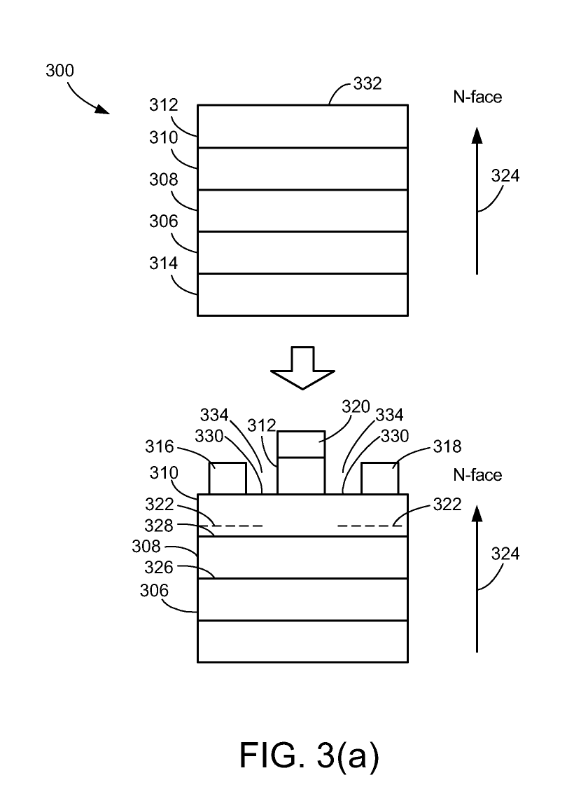

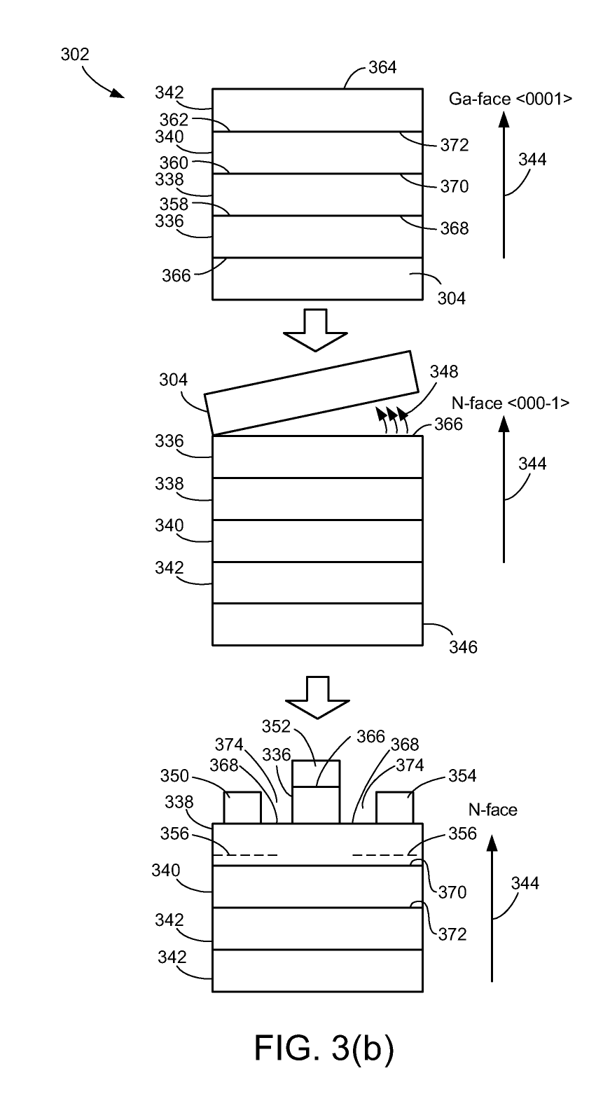

In FIGS. 3(a) and 3(b), N-polar enhancement-mode gallium nitride (GaN) based devices 300, 302 grown and processed conventionally (FIG. 3(a)) and on a silicon substrate 304 (FIG. 3(b)) are compared, as a demonstration of how the method of the present invention may be used.

In FIG. 3(a), the device layers, comprising a first GaN layer 306, a first AlGaN layer 308, a second GaN layer 310 and a second AlGaN layer 312, are grown on a substrate for N-polar growth 314 and then subsequently processed to form a source 316, drain 318 and a gate 320, wherein the dotted line 322 indicates the position of the device's two dimensional electron gas (2DEG) 322.

The arrow 324 points in the N-face <000-1> direction, which is also the growth direction. The as grown N-face device 300 has layer 306 deposited on the substrate 314, layer 308 deposited on layer 306, layer 310 deposited on layer 308 and layer 312 deposited on layer 310. In addition, growth in the N-face direction means layers 306-312 each have last grown surfaces 326-332, respectively, which are an N-faces.

The gate 320 is deposited/processed on the N-face 332 of the second AlGaN layer 312, and the AlGaN layer 312 is at least partially removed 334 to expose the N-face surface 330 of the second GaN layer 310 so that the source 316 and drain 318 may be deposited/processed on the N-face surface 330. In this way, one or more N-face surfaces 330, 332 of the device 300 are processed.

In FIG. 3(b), the device layers, comprising a first AlGaN layer 336, a first GaN layer 338, a second AlGaN layer 340, and a second GaN layer 342, are grown on a silicon substrate 304 in the Ga-face direction (as indicated by arrow 344), attached to a host substrate 346, the silicon substrate 304 is removed 348, and then the device 302 is processed with a source 350, gate 352 and drain 354, for example.

The first AlGaN layer 336 is grown on the substrate 304, the first GaN layer 338 is grown on the AlGaN layer 336, the second AlGaN layer is 340 grown on the GaN layer 338, and the second GaN layer 342 is grown on the second AlGaN layer 340. The dotted line 356 shows the position of the device's 2DEG.

This results in an N-polar (000-1) oriented III-nitride semiconductor device 302, comprising one or more (000-1) oriented nitride layers 336-342, each having a group III-face 358-364 opposite an N-face 366-372, wherein at least one N-face 366, 368 is at least partially exposed, and a host substrate 346 attached to a terminating group III-face 364. If the layers 336-342 form a stack, then the group III-face 364 terminates the stack.

Specifically, the AlGaN nitride layer 336 has a Ga-face 358 opposite an N-face 366, the GaN nitride layer 338 has a Ga-face 360 opposite an N-face 368, the AlGaN nitride layer 340 has a Ga-face 362 opposite an N-face 370, and the GaN nitride layer 342 has a Ga-face 364 opposite an N-face 372. The Ga-faces 358-364 are the last grown surfaces of the layers 336-342, respectively.

One or more N-faces 366-372 of the device 302 may be processed. When the Si substrate 304 is removed, the N-face surface 366 of the first AlGaN layer 336 is exposed and processed with the gate 352. Furthermore, the AlGaN layer 336 is partially removed 374 to at least partially expose the N-face surface 368 of the GaN layer 338 so that the source 350 and drain 354 may be deposited on the N-face 368 of the GaN layer 338. Generally, because the substrate 304 has been removed, the N-face surfaces 368, 370 and 372 may be exposed by selectively etching or removing layers 336, 338 and 340 respectively. In this way, a device is fabricated by growing the semiconductor device structure 336-342 in the Ga-face or III-face orientation, and processing the semiconductor nitride device in the nitrogen face (N-face) orientation, by processing one or more N-faces of the device 366-372 with a source 350, gate 352, and drain 354, or etching 374 (in a manner similar to processing as-grown N-face devices 300 (FIG. 3(a)).

The present invention allows the fabrication of E-mode HEMT structures using conventional growth techniques. However, devices such as discrete transistors, integrated transistor circuits, or optoelectronic devices may also be fabricated using this method. Therefore, any number of device layers may be grown. Moreover, the Ga-faces in the above discussion may be group III-faces, and growth in the Ga-polar direction is equivalent to growth in the III-polar or III-face orientation or metal face orientation.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching, without fundamentally deviating from the essence of the present invention. It is intended that the scope of the invention be limited not by this detailed description, but rather by the claims appended hereto.

What is claimed is:

1. A method for fabricating III-nitride semiconductor devices on the nitrogen-face (N-face) of layers, comprising:
(a) growing a III-nitride semiconductor device structure in a III-polar direction on a growth substrate;
(b) attaching a III-face of the III-nitride semiconductor device structure to a host substrate; and
(c) at least partially removing the growth substrate to expose a nitrogen-face of the III-nitride semiconductor device structure.

2. The method of claim 1, further comprising using or processing one or more exposed nitrogen faces of the semiconductor device structure to form a device.

3. The method of claim 1, wherein the growth substrate is silicon.

4. A device fabricated using the method of claim 1.

5. The device of claim 3, wherein the device is a High Electron Mobility Transistor (HEMT).

6. A nitrogen polar (N-polar) (000-1) oriented III-nitride semiconductor device, comprising:
(a) one or more (000-1) oriented nitride layers, each having a nitrogen (N-face) opposite a group III-face, wherein at least one N-face is at least partially exposed; and
(b) a host or carrier substrate attached to a terminating group III-face.

7. The device of claim 6, wherein one or more of the N-faces is processed.

8. The device of claim 6, further comprising a stack of the (000-1) oriented nitride layers, and the host substrate is attached to a group III-face terminating the stack.

9. The device of claim 8, wherein:
(1) the one or more (000-1) oriented nitride layers are a first AlGaN layer, a first GaN layer on the first AlGaN layer, a second AlGaN layer on the first GaN layer, a second GaN layer on the second AlGaN layer;
(2) a two dimensional electron gas is confined in the second GaN layer;
(3) a gate is on the at least partially exposed N-face of the first AlGaN layer; and
(4) a source and a drain electrically contacting the at least partially exposed N-face of the first GaN layer.

10. The device of claim 8, wherein the device is a high electron mobility transistor (HEMT).

11. A method for fabricating III-nitride semiconductor devices, comprising:
(a) growing the semiconductor device in the gallium (Ga-face) or III-face orientation; and
(b) processing the semiconductor nitride device in the nitrogen face (N-face) orientation, by processing one or more N-faces of the device.
